(19) United States
(12) Patent Application Publication
(10) Pub. No.: US 2005/0199913 A1
(43) Pub. Date: Sep. 15, 2005

(54) Word and bit line arrangement for a FinFET semiconductor memory

(76) Inventors: Franz Hofmann, Munchen (DE); Thomas Schulz, Austin, TX (US); Michael Specht, Munchen (DE)

Correspondence Address: MOSER, PATTERSON & SHERIDAN, LLP;GERO G. MCCLELLAN/INFINEON, 3040 POST OAK BLVD.,, SUITE 1500, HOUSTON, TX, 77056, US

(21) Appl. No.: 11/074,345

(22) Filed: Mar. 7, 2005

Related U.S. Application Data
(63) Continuation of application No. PCT/EP03/09294, filed on Aug. 21, 2003.

(30) Foreign Application Priority Data
Sep. 5, 2002 (DE) DE 102 41 171.9

(51) Int. Cl. H01L 27/105; H01L 21/336

(52) U.S. Cl. 257/204; 257/401; 257/315; 438/257

(57) ABSTRACT

The invention relates to a semiconductor memory having a multiplicity of fins made of semiconductor material which are spaced apart from one another, a multiplicity of channel regions and contact regions being formed in each of the fins, a multiplicity of word lines, a multiplicity of storage layers, at least one of the storage layers being arranged between each of the channel regions and the word line, and a multiplicity of bit lines, the longitudinal axes of first bit line portions running parallel to a first bit line direction and the longitudinal axes of second bit line portions running parallel to a second bit line direction, the second bit line direction being rotated relative to the first bit line direction, each of the bit lines being electrically connected to a multiplicity of the contact regions, wherein, between two contact regions of the same fin that are connected to one of the bit lines, a contact region is not connected to the respective bit line.

### CROSS-REFERENCE TO RELATED APPLICATIONS

This application is a continuation of co-pending PCT patent application No. PCT/EP03/09294, filed 21 Aug. 2003, which claims the benefit of German patent application serial number DE 102 41 171.9, filed 5 Sep. 2002. Each of the aforementioned related patent applications is herein incorporated by reference in their entireties.

### BACKGROUND OF THE INVENTION

1. Field of the Invention

The invention relates to a semiconductor memory, and more particularly, to a semiconductor memory having FinFET elements.

2. Description of the Related Art

Conventional non-volatile semiconductor memory elements exist in a multiplicity of different embodiments, e.g., PROM, EEPROM, FLASH EEPROM and SONOS, depending on the application. These various embodiments differ in particular in terms of erasure option, programmability and programming time, retention time, storage density and also in terms of their production costs. There is a particular need for high-density and inexpensive FLASH semiconductor memory elements. Known embodiments are in particular so-called NAND and ETOX memory cells, but the storage density thereof requires more than 4F², where F is the smallest semiconductor memory feature size occurring in the process.

The publication by B. Eitan et al. “NROM: A novel localized trapping, 2-bit non-volatile Memory Cell”, IEEE Electron Device Letters vol. 21, n.11 November 2000, describes a so-called NROM memory cell which, with the aid of a cell that can store two bits, enables a cell having an area dimension of 2F². However, the scalability of such NROM memory cells, which constitute planar components, as also in the case of other conventional EEPROM memories having trapping layers (for example, oxide-nitride-oxide trapping layers or so-called ONO stacks), is limited. For programming the trapping layer, such components utilize, in a known manner, channel hot electrons (CHE) that are injected into the trapping layer from the transistor channel as a result of suitable potential conditions at the source, drain and gate contacts.

The abovementioned scaling problem can be improved by means of memory arrangements having so-called FinFETs, in which the transistor channel is formed in a ridgelike fin made of semiconductor material. It is furthermore advantageous in this case that the read current of the memory element can be set through the height of the fin. Since the gate electrodes in FinFET memory arrangements of this type surround the finlike transistor channel regions from three sides, short channel effects, which restrict scalability, can be effectively suppressed given a suitable choice of the transistor parameters.

FinFET memory arrangements in which the word line run parallel to the fin longitudinal direction (fin direction) have been proposed (cf. DE 102 11 931.7) as particularly advantageous. In the case of very high cell array densities of such semiconductor memories, use has been made of FinFET memory arrangements in which the silicon fins that are spaced apart from one another and arranged parallel to one another are at a distance of less than 50 nm from one another (smallest feature size F less than 50 nm). However, the word lines running between two adjacent fins in the direction of the fin longitudinal axes thereof can easily be short-circuited in the case of such dimensions.

Accordingly, there is a need for a semiconductor memory which enables a high-density cell array without having the above short-circuit problems.

### SUMMARY OF THE INVENTION

According to one embodiment of the invention, a semiconductor memory comprises: a multiplicity of ridgelike fins made of semiconductor material which are spaced apart from one another and the fin longitudinal directions of which run parallel to one another, a multiplicity of channel regions and conductively doped contact regions being formed in each of the fins and the channel and contact regions being arranged alternately one after the other in the fin longitudinal direction; a multiplicity of word lines which are arranged perpendicular to the fin longitudinal direction, which are parallel to one another and which, as gate electrodes, run over a multiplicity of the channel regions to control the electrical conductivities thereof, the word lines being electrically insulated from the contact and channel regions; a multiplicity of storage layers designed for trapping and outputting charge carriers, at least one of the storage layers being arranged in a manner surrounded by an insulator layer between each of the channel regions and the word line assigned to this channel region; and a multiplicity of bit lines which are arranged obliquely with respect to the word line longitudinal direction and obliquely with respect to the fin longitudinal direction, the bit lines in each case comprising at least one first and one second bit line portion, the longitudinal axes of the first bit line portions running parallel to a first bit line direction and the longitudinal axes of the second bit line portions running parallel to a second bit line direction, the second bit line direction being rotated by an angle that differs from zero degrees relative to the first bit line direction; and each of the bit lines being electrically connected to a multiplicity of the contact regions, there being arranged, between two contact regions of the same fin that are connected to one of the bit lines, a contact region that is not connected to this bit line.

The semiconductor memory according to one embodiment of the invention utilizes so-called FinFETs as “memory transistors”. In this case, the transistor channel is formed in a ridgelike semiconductor fin with doped contact regions adjoining in the fin longitudinal direction. The electrical conductivity of the transistor channel, i.e., of the channel region, can be controlled by means of the field effect via a (control) gate electrode in a known manner. A storage layer is arranged between the gate electrode, which constitutes one of the word lines of the semiconductor memory, and the channel region. The storage layer is electrically isolated from its surroundings, in particular from the channel region and the gate electrode, by means of a thin insulator layer. However, charge carriers, for example, electrons in the case of an n-channel FinFET, given suitable source, drain and gate potentials, can acquire such an energy (hot electrons) that they can overcome the fin insulator layer and be permanently trapped by the storage layer. A charge introduced into the storage layer in this way can be used for storing a “bit” in non-volatile fashion since it influences the characteristic curve, in particular the threshold voltage of the FinFET. These different threshold voltages can be used for the “read-out” of the memory cell. In particular, the read method which is described in the above publication by B. Eitan et al., and which is likewise described in the international patent application WO 99/97000, can be used in this connection. With regard to the programming, reading and erasing method for the semiconductor memory according to embodiments of the invention, reference is thus made to these above publications in their entirety, which are incorporated by reference in their entireties and in this respect form an integral part of the disclosure of the present application.

The problem mentioned in the introduction, namely that, in the case of high-density memory cell arrays, word lines running parallel to the fin longitudinal direction between two adjacent fins can be short-circuited, is solved by embodiments of the invention by virtue of the fact that the word lines are arranged essentially perpendicular to the fin longitudinal direction. At the same time, the bit lines via which the highly doped contact regions (source and drain contacts) of the FinFETs can be contact-connected are arranged obliquely with respect to the fin longitudinal direction and likewise obliquely with respect to the word line direction. There is thus an angle that differs from 0° between the word lines and each of the bit lines. Equally, there is an angle that differs from 0° between the fin longitudinal direction and the longitudinal direction of the bit line.

A further measure according to embodiments of the invention that improves the properties of the semiconductor memory is that each of the bit lines comprises at least two bit line portions. The two bit line portions of each bit line are rotated by an angle with respect to one another in the bit line plane, so that the first bit line direction does not correspond to the second bit line direction. This avoids large length differences between the bit lines which might lead to difficulties during the read-out of the memory cell array on account of different bit line impedances, propagation time effects, etc. If the bit lines comprised a single straight portion arranged obliquely with respect to the word line longitudinal direction and also the fin longitudinal axes, bit lines which electrically connect only a single contact region and bit lines which extend along the entire diagonal of the memory cell array would result in the extreme case.

The two bit line portions may be connected to one another directly above a contact region, so that the “change in direction” of the bit line is effected in the region of the highly doped contact regions. Between these “changes in direction”, the bit line portions extend as straight metal tracks in a bit line plane.

Advantages of the semiconductor memory according to embodiments of the invention include that a read current may be set in a variable manner through variation of the height of the fin, which can be tailored to “high performance” or “low-power” applications. The so-called “double gate” effect of the FinFET arrangement permits potentially better scalability in comparison with planar components, for example, NROM memories. Furthermore, on account of the metallic bit lines, the semiconductor memory according to embodiments of the invention permits faster access times as a result of lower line resistances (shorter RC times when driving parasitic capacitances). The novel arrangement of word and bit lines enables particularly high storage densities even for very small fin spacings of less than 50 nm (F<50 nm).

In one embodiment, each of the bit lines comprises a multiplicity of bit line portions having alternately a first and second bit line direction. The bit lines may have a so-called sawtooth shape, in the case of which the bit lines are arranged in sawtooth-shaped or zigzag-shaped fashion in a bit line plane. In this case, the bit line direction of bit line portions that are connected to one another alternates along the bit line between the first and the second bit line direction.

The bit line portions may have identical lengths. All of the bit lines may be configured as regular sawtooth patterns whose teeth partly intermesh, so that the cell array (apart from possible edge regions) can be completely contact-connected.

In one embodiment, a number N_{fins} of the fins is provided in each memory sector, and each of the bit line portions is electrically connected to at most N_{fins}/10 of contact regions of different fins that are adjacent in the bit line direction. Consequently, the bit line portions extend only over a small part of the entire cell array and cross in particular at most a tenth of the fins present in the cell array. In the case of typical cell array sizes of 256×256 word and bit lines, the “amplitude” of the sawtooth pattern is thus less than approximately 25 fins, and in one embodiment, less than 10 fins.

In one particular arrangement, each bit line electrically connects, in sawtooth-shaped fashion, the contact regions that are diagonally adjacent in the cell array. In the case of such a bit line arrangement, a “change in direction” accordingly takes place on each contact region that is electrically connected to the bit line.

The bit lines may have identical area configurations. In particular, the area configurations may be transferred into one another in the bit line plane by means of a parallel displacement along the word line longitudinal direction by a fin period (pitch).

In one embodiment, each of the bit lines is connected to at least Nₘᵢₙ and at most Nₘₐₓ of the contact regions, so that ((Nₘₐₓ−Nₘᵢₙ)/Nₘₐₓ)<20% holds true. The relative deviation in the number of contact regions to which the bit lines are electrically connected thus lies within a range of fluctuation of less than 10%. Consequently, the bit lines have only slightly different numbers of contact regions that are electrically connected to them. This leads to only small variation of electrical characteristic quantities of the bit line, in particular in the impedance thereof, so that evaluation electronics connected to the bit lines may be tuned more simply. Ideally, all of the bit lines have an essentially identical number of contact regions connected to them, so that the bit lines have the same “electrical length”.

In one embodiment, the fin width is equal to the word line width and equal to the perpendicular distance between adjacent word lines. The fin width, i.e., the perpendicular distance between the opposite fin side areas running parallel, is chosen to be equal to the word line width and the word line spacing, thus resulting in a square 1:1 cell array grid. Such a cell array arrangement enables the highest storage density.

In one embodiment, two bit line planes are provided, and bit lines that are adjacent in the word line longitudinal direction are arranged in different bit line planes. Such an embodiment is of interest particularly when, as described above, the fin width, bit line width, word line width and the word line spacing correspond to the minimum feature size F of the semiconductor memory. In such a case, a sawtooth-shaped bit line leads to distances between adjacent bit lines which would be smaller than the minimum feature size F. This problem can be solved by arranging respectively adjacent bit lines in different bit line planes, i.e., in different metal planes. By way of example, the odd bit lines are provided in a first bit line plane, and the even bit lines are provided in a second bit line plane (located at a higher level) that is further away from the semiconductor substrate. The higher bit line plane is connected by means of deep contact holes to the contact regions of the FinFETs that are to be connected. A 4F² memory cell that can store two bits can be obtained with a bit line arrangement of this type. The programming and read concept known from NROM memories is used in this case.

In one embodiment, the bit line directions are rotated by an angle of approximately 45 degrees relative to the word line and fin longitudinal directions and the angle between the first and the second bit line direction is 90°. Such an arrangement is advantageous particularly in the case of a memory cell array having a square 1:1 arrangement of the cells and permits a symmetrical configuration of the bit lines.

The storage layers are trapping layers and the insulator layers are oxide layers. The trapping layer may be a nitride layer, in particular a silicon nitride layer, which is surrounded by oxide layers, in particular silicon dioxide layers. Such an oxide-nitride-oxide arrangement between the (control) gate electrode and the channel region is referred to as an ONO stack. However, it is also possible to use other trapping materials, for example, so-called “silicon-rich oxide” or else undoped polysilicon or other high-k materials. Such trapping layers have a large density of defect states (so-called “trap states”) which are suitable for trapping and emitting charge carriers (electrons or holes).

The invention thus provides a non-volatile semiconductor memory in a “virtual ground” arrangement (VGA) with a cell array density of 2F² per bit, in the case of which the bit lines lie in sawtooth-shaped fashion and alternately in the first and second metal planes (bit line planes). This results in a memory arrangement having the storage density of planar NROMs, with the advantage of an adjustable read current, the “double gate” effect by virtue of the FinFET arrangement and thus, a potentially better scalability and also a faster access time to each memory cell by virtue of the metallic bit lines. The very high storage density of 2F² per bit may also be achieved for fins that are very close together where F<50 nm.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 shows a simplified schematic cross-sectional view of a first FinFET arrangement which is particularly suitable for a semiconductor memory according to embodiments of the invention;

FIG. 2 shows a simplified schematic cross-sectional view of a second FinFET arrangement which is particularly suitable for a semiconductor memory according to embodiments of the invention;

FIG. 3 shows a simplified schematic cross-sectional view of a third FinFET arrangement which is particularly suitable for a semiconductor memory according to embodiments of the invention;

FIG. 4 shows a simplified plan view of a memory cell array of a semiconductor memory according to one embodiment of the invention in which the sawtooth-shaped bit lines are arranged alternately in the first and second metal planes;

FIG. 5 shows a greatly simplified cross-sectional view along the line A-A of FIG. 4 for illustrating the course of the bit lines; and

FIG. 6 shows a simplified plan view of a memory cell array of a semiconductor memory according to another embodiment of the invention in which the sawtooth-shaped bit lines run in the same metal plane.

### DETAILED DESCRIPTION OF THE PREFERRED EMBODIMENT

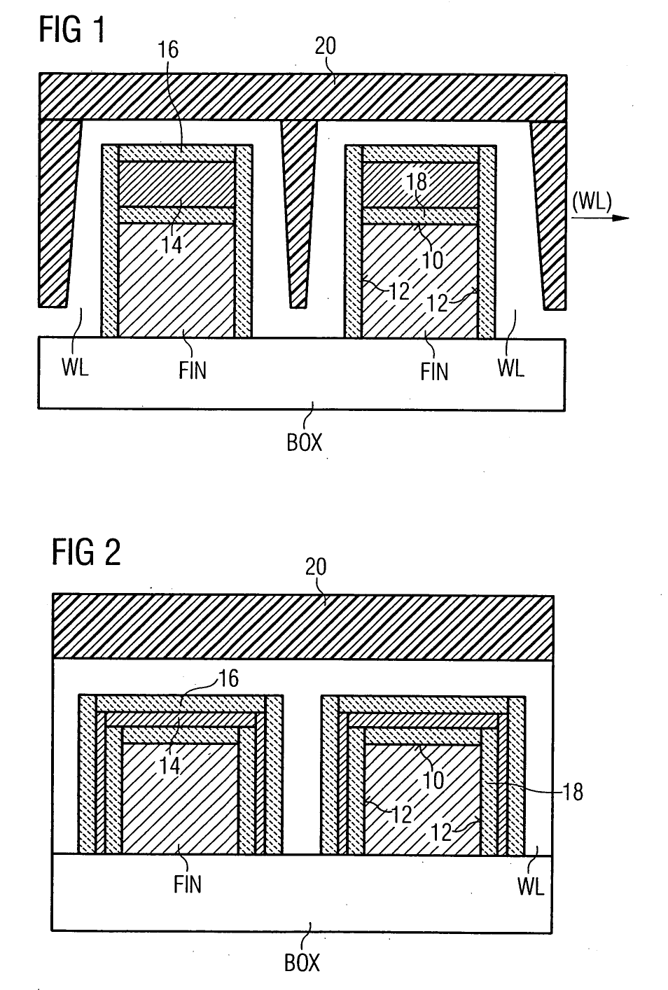

FIG. 1 shows a simplified cross-sectional view of a FinFET arrangement which is particularly suitable for a semiconductor memory according to embodiments of the invention. For the sake of better clarity, the depiction of bit lines and structures situated at a higher level has been dispensed with in this cross-sectional view.

The cross-sectional view illustrated in FIG. 1 runs in a plane that is perpendicular to the fin longitudinal direction of the fins FIN. In this embodiment, the fins FIN have a generally rectangular cross-section with a fin top side 10 and opposite fin side areas 12. The sectional plane of FIG. 1 runs through a word line WL along the longitudinal direction thereof. The word line longitudinal direction is illustrated by a direction arrow designated by (WL). A storage layer 14 is provided between the word line WL and the channel region formed in the fin FIN, the storage layer being a trapping layer. The storage layer 14 may be composed of nitride which is surrounded by thin oxide walls 16.

Hot electrons generated in the transistor channel as a result of suitable potential conditions can overcome the oxide layer 18 and penetrate into the storage layer 14 as so-called “channel hot electrons” (CHE). Their presence in the storage layer 14 brings about, in a known manner, a shift in the threshold voltage of the FinFET, as a result of which a “bit” can be programmed. The scalability of the FinFET is improved compared with planar components on account of the “double gate” effect of the word line WL on the channel region, in particular from the fin side areas 12. To produce such FinFET arrangements, SOI substrates (silicon on insulator) are suitable, in particular, in the case of which the ridgelike fins made of semiconductor material, e.g., silicon, are arranged on a buried oxide layer BOX which, for its part, is applied on a silicon substrate. The fins FIN are formed in the top silicon layer (body silicon layer).

The width of the fins FIN illustrated in FIG. 1, i.e., the perpendicular distance between opposite fin side areas 12, may be less than 100 nm, and particularly in one embodiment, less than 50 nm. The entire structure is surrounded by an insulator layer 20, in particular a nitride layer.

FIG. 2 shows another FinFET arrangement which is particularly suitable for a semiconductor memory according to embodiments of the invention. In this case, the sectional direction corresponds to that of FIG. 1 and identical or similar features are provided with identical reference symbols, so that a renewed description can be dispensed with.

Whereas in the case of the FinFET arrangement illustrated in FIG. 1, the storage layer 14 is arranged such that it is spaced apart from the fin top side 10 by an oxide layer 18, the storage layer 14 also extends along the fin side areas 12 in the case of the variant illustrated in FIG. 2. In a customary manner, the storage layer 14 is isolated from the contact regions (not illustrated) and the channel region of the fin FIN and also the word line (gate electrode) by insulator layers 16, 18. The storage layer arrangement lying between the word line WL and the fin FIN may comprise a so-called ONO stack, in which a silicon nitride layer is embedded between two silicon dioxide layers. In accordance with the structure of the storage layer 14, the FinFET variant illustrated in FIG. 2 is referred to as a so-called “wrap around” memory FinFET.

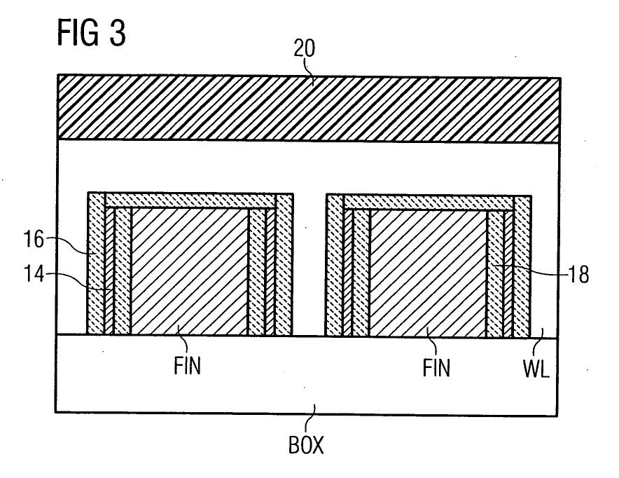

FIG. 3 illustrates a further variant of a FinFET arrangement which is likewise particularly suitable for a semiconductor memory according to embodiments of the invention. The sectional plane of FIG. 3 corresponds to that of FIGS. 1 and 2. In contrast to FIG. 2, in the case of the FinFET variant illustrated in FIG. 3, the storage layer 14 is only arranged along the fin side areas 12 in a manner isolated by an insulator layer 18. No storage layer 14 is provided on the fin top side 10, by contrast, so that a so-called “two-sided ONO” memory FinFET is formed.

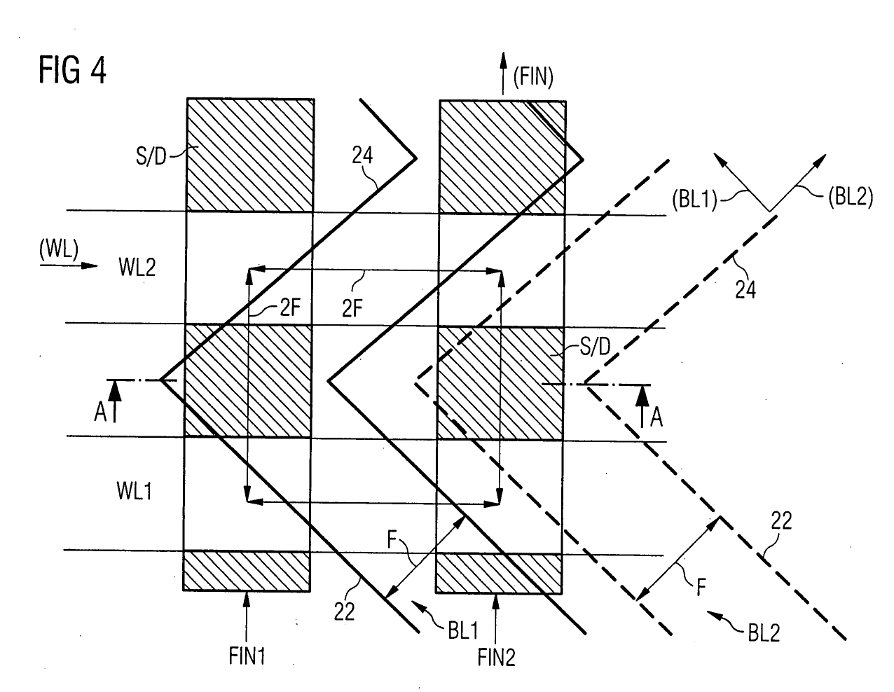

FIG. 4 shows a simplified plan view of a semiconductor memory according to a first embodiment of the invention.

The ridgelike fins made of semiconductor material FIN1, FIN2 run from top to bottom in the plane of the drawing. The fin longitudinal direction is illustrated by the direction arrow designated by (FIN). In the embodiment illustrated in FIG. 4, fins FIN1, FIN2 have a fin width F corresponding to the minimum structure width of the semiconductor memory. Highly and lightly doped semiconductor sections are provided alternately in the fin longitudinal direction (FIN). The highly doped sections, which are emphasized by a hatched pattern in FIG. 4, form the electrically conductively doped contact regions S/D (source and drain regions of the FinFETs). A channel region in which the FinFET channel is formed is respectively arranged between two contact regions S/D that are adjacent in the fin longitudinal direction (FIN).

The word lines WL1, WL2 run perpendicular to the fin longitudinal direction (FIN). The direction of the word lines is illustrated by the direction arrow designated by (WL). The word lines WL1, WL2 form the (control) gate electrodes of the FinFETs and run over the channel regions of the fins FIN1, FIN2. Each word line WL1, WL2 has precisely one crossover point with each fin FIN1, FIN2. In the case of the embodiment illustrated in FIG. 4, the width of the word lines WL1, WL2 and also the distance between adjacent word lines are F, i.e., the minimum structure width of the semiconductor memory. Bit lines BL1, BL2 run in sawtooth-shaped fashion above the matrix-type cell array formed by the word lines WL1, WL2 and the fins FIN1, FIN2.

The bit lines BL1, BL2 are comprised of a multiplicity of bit line portions 22, 24 connected to one another. The first bit line portion 22 runs in a first bit line direction (BL1) while the second bit line portion 24 runs along a second bit line direction (BL2). The bit line directions (BL1), (BL2) run obliquely with respect to the word line longitudinal direction (WL) and the fin longitudinal direction (FIN). In the case of the embodiment illustrated in FIG. 4, the angle of inclination of the bit line directions (BL1), (BL2) with respect to the word line longitudinal direction (WL) and the fin longitudinal direction (FIN) is in each case approximately 45°. In one embodiment, each of the bit lines BL1, BL2 runs in sawtooth-shaped fashion between two adjacent fins FIN. By way of example, the bit line BL1 runs in sawtooth-shaped fashion between the fin FIN1 and the fin FIN2, each of the bit line portions 22, 24 extending in the bit line direction (BL1) and (BL2), respectively, between the fins FIN1 and FIN2.

The bit lines BL1, BL2 run over the contact regions S/D formed in the fins FIN1, FIN2. The metallic bit lines BL are electrically connected to the underlying contact regions S/D through contact holes. In the case of the embodiment illustrated in FIG. 4, the width of the bit lines BL is equal to the minimum structure width F of the semiconductor memory. This has the effect that the minimum distance between adjacent bit lines BL in a bit line plane would turn out to be less than the minimum feature size F. This problem is solved by virtue of the fact that the bit lines BL are formed alternately in the first and second metal planes (first and second bit line planes). By way of example, the bit line BL1 is formed in the first (bottommost) metal plane and is illustrated by solid lines in FIG. 4. The bit line BL2, by contrast, is formed in the next higher, second metal plane and is depicted as a dotted line in FIG. 4. This enables a high-density memory cell array with a 4F² memory cell that can store two bits. The 4F² memory cell is depicted schematically in FIG. 4.

Although the sawtooth-shaped bit line course depicted in FIG. 4 represents the most preferred embodiment variant of a semiconductor memory according to the invention, it is also possible to use other bit line patterns that run in an oblique manner. Preference is attached for example to a bit line arrangement which does not just merely connect two adjacent fins FIN1, FIN2 to one another, but rather a larger number (for example, less than 20 or less than 10). The pattern of the course of the bit lines BL may be identical in the bit line planes so that the bit lines BL have the same area configuration. In particular, each bit line may be transferred into the area configuration of the adjacent bit line by means of a parallel displacement in the word line longitudinal direction (WL) by a fin period (i.e., pitch; 2F).

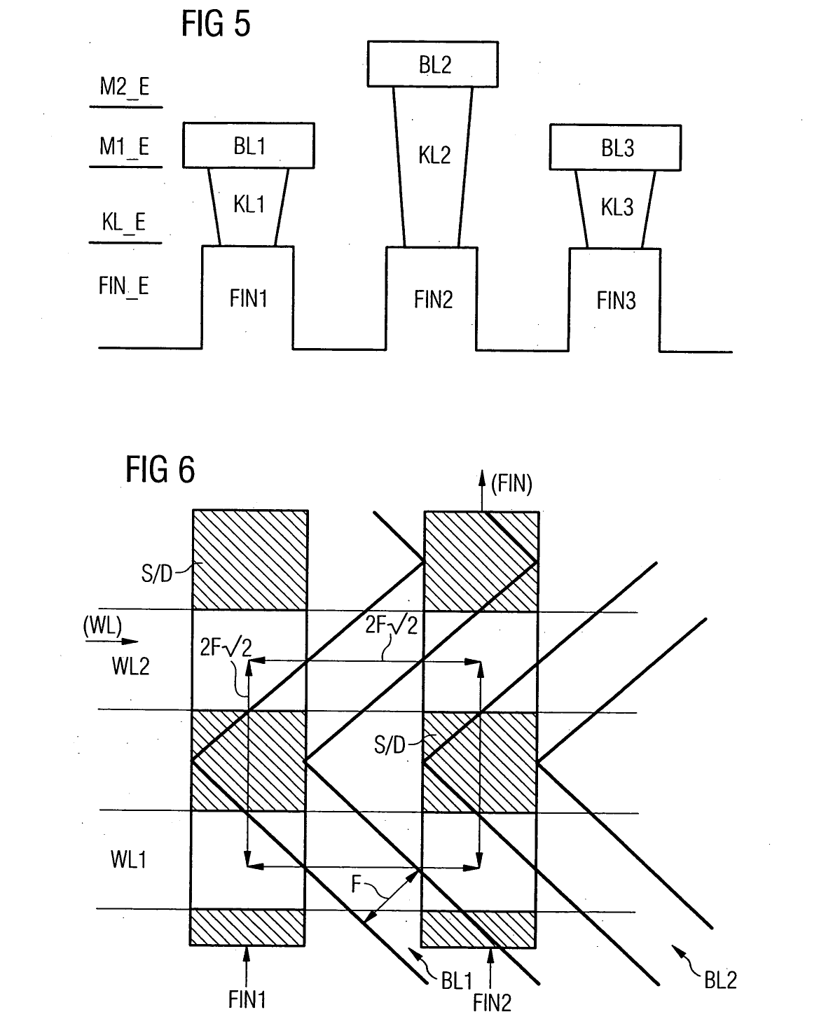

FIG. 5 shows a greatly simplified cross-sectional view along the line A-A of FIG. 4. The fins FIN1, FIN2 and FIN3 are only illustrated schematically. The fins FIN1, FIN2, FIN3 are formed in the FinFET plane designated by FIN_E. A contact hole plane KL_E is present above the FinFET plane FIN_E, through which contact hole plane the contacts KL1 and KL3 extend from the overlying first metal plane M1_E to the contact regions S/D of the FinFETs. Situated between two bit lines BL1, BL3 formed in the first metal plane (first bit line plane) M1_E is a bit line BL2 running in the overlying second metal plane M2_E. The metallic bit line BL2 is connected to the contact region S/D of the fin FIN2 via a “deep” contact KL2. The bit lines thus run alternately in the first M1_E and second M2_E metal plane, so that the distance between the planes may be less than the minimum feature size F.

FIG. 6 shows a semiconductor memory according to a second embodiment of the invention in a schematic plan view. Features that have already been described in connection with FIG. 4 bear the same reference symbols and are not described again. In contrast to the embodiment described with reference to FIG. 4, the memory cell array of FIG. 6 only has bit lines BL in a single metal plane (bit line plane). Given a minimum structure width F of the semiconductor memory that corresponds to the width of the bit line BL, it is thus necessary to choose a different dimensioning of the fin width of the fins FIN1, FIN2 and also of the word lines WL1, WL2 and of the word line spacing. Since the bit lines BL run at an angle of 45° to the word line longitudinal direction (WL) and the fin longitudinal direction (FIN), the fin and word line widths and also the word line spacing are F\sqrt{2}. The memory cell is thus enlarged to a 2F\sqrt{2}×F\sqrt{2}=8F² memory cell. The integration density of the memory cell array in a “virtual ground array (VGA)” arrangement as illustrated in FIG. 6 is thus less than that of FIG. 4. However, the production process is simpler on account of the just one bit line plane required.

While the foregoing is directed to embodiments of the present invention, other and further embodiments of the invention may be devised without departing from the basic scope thereof, and the scope thereof is determined by the claims that follow.

1. A semiconductor memory, comprising:
a plurality of ridgelike fins made of semiconductor material which are spaced apart from one another, wherein fin longitudinal directions of which run parallel to one another;
a plurality of channel regions and conductively doped contact regions formed in each of the fins, wherein the channel and contact regions are arranged alternately one after the other in the fin longitudinal direction;
a plurality of word lines arranged perpendicularly to the fin longitudinal direction and electrically insulated from the contact and channel regions, wherein the plurality of word lines are parallel to one another and run over the plurality of the channel regions, wherein portions of the plurality of word lines disposed over the plurality of channel regions form respective gate electrodes to control electrical conductivities of the plurality of channel regions;
a plurality of storage layers configured for trapping and outputting charge carriers, at least one of the storage layers arranged in a manner surrounded by an insulator layer between each of the channel regions and the word line assigned to the channel regions; and
a plurality of bit lines arranged obliquely with respect to a word line longitudinal direction and obliquely with respect to the fin longitudinal direction, each bit line comprising at least one first bit line portion and at least one second bit line portion, the longitudinal axes of the first bit line portions running parallel to a first bit line direction and the longitudinal axes of the second bit line portions running parallel to a second bit line direction, the second bit line direction rotated by an angle that differs from zero degrees relative to the first bit line direction, wherein each bit line is electrically connected to alternating contact regions on at least two fin longitudinal directions.

2. The semiconductor memory of claim 1, wherein each bit lines comprises a plurality of bit line portions having alternately the first bit line direction and the second bit line direction.

3. The semiconductor memory of claim 1, wherein the bit line portions have substantially identical lengths.

4. The semiconductor memory of claim 1, wherein a number N_{fins} of the fins are provided in each memory sector, and wherein each of the bit line portions are electrically connected to at most N_{fins}/10 of the contact regions of different fins that are adjacent in the bit line directions.

5. The semiconductor memory of claim 1, wherein the bit lines have substantially identical area configurations.

6. The semiconductor memory of claim 1, wherein each of the bit lines are connected to at least Nₘᵢₙ and at most Nₘₐₓ of the contact regions, wherein (Nₘₐₓ Nₘᵢₙ)/Nₘₐₓ is less than 20 percent.

7. The semiconductor memory of claim 1, wherein a fin width is equal to a word line width and also equal to a perpendicular distance between adjacent word lines.

8. The semiconductor memory of claim 1, wherein the bit lines that are adjacent in a word line longitudinal direction are arranged in different bit line planes.

9. The semiconductor memory of claim 1, wherein the bit line directions are rotated by an angle of approximately 45 degrees relative to the word line and fin longitudinal directions and the angle between the first bit line direction and the second bit line direction is about 90 degrees.

10. The semiconductor memory of claim 1, wherein the storage layers are trapping layers and the insulator layers are oxide layers.

11. The semiconductor memory of claim 10, wherein the semiconductor material comprises silicon, wherein the trapping layers comprise silicon nitride layers and wherein the oxide layers comprise silicon dioxide layers.

12. A memory apparatus, comprising:
a plurality of FinFETs disposed in a plurality of parallel fin longitudinal directions, each FinFET comprising:
a channel region and a conductively doped contact region formed arranged alternately in the fin longitudinal direction on a semiconductor material fin; and
a storage layer configured for trapping and outputting charge carriers, disposed in a manner surrounded by an insulator layer between the channel region and a word line assigned to the respective channel region;
a plurality of parallel word lines disposed perpendicularly to the fin longitudinal direction over a plurality of channel regions, wherein the word lines are electrically insulated from the contact and channel regions; and
a plurality of bit lines disposed obliquely with respect to a word line longitudinal direction and obliquely with respect to the fin longitudinal direction, each bit line comprising first bit line portions in a first bit line direction alternating with second bit line portions in a second bit line direction, wherein each bit line is electrically connected to alternating contact regions on at least two fin longitudinal directions.

13. The memory apparatus of claim 12, wherein the bit line directions are rotated by an angle of approximately 45 degrees relative to the word line and fin longitudinal directions and the angle between the first bit line direction and the second bit line direction is about 90 degrees.

14. The memory apparatus of claim 13, wherein a fin width is equal to a word line width and is also equal to a perpendicular distance between adjacent word lines, wherein a bit line width is equal to the fin width divided by \sqrt{2}, and wherein the bit lines are disposed on a single plane.

15. The memory apparatus of claim 13, wherein a fin width is equal to a word line width, is equal to a perpendicular distance between adjacent word lines and is equal to a bit line width, and wherein adjacent bit lines are disposed in different bit line planes.

16. The memory apparatus of claim 12, wherein the memory apparatus comprises a plurality of memory sectors, wherein a number N_{fins} of the fins are provided in each memory sector, and wherein each of the bit line portions are electrically connected to at most N_{fins}/10 of the contact regions of different fins that are adjacent in the bit line directions.

17. The memory apparatus of claim 12, wherein each of the bit lines are connected to at least Nₘᵢₙ and at most Nₘₐₓ of the contact regions, wherein (Nₘₐₓ Nₘᵢₙ)/Nₘₐₓ is less than 20 percent.

18. A method for forming a semiconductor memory apparatus, comprising:
forming a plurality of FinFETs on a plurality of semiconductor material fins;
forming a plurality of parallel word lines perpendicularly to the fins; and
forming a plurality of bit lines disposed in a sawtooth-shaped pattern, wherein each bit line is electrically connected to alternating FinFETs on at least two fins.

19. The method of claim 18, wherein a fin width is equal to a bit line width, and wherein forming the plurality of bit lines comprises:
forming a first set of bit lines in a first metal plane, the first set of bit lines connected to a first set of FinFETs by first contacts having a first height; and
forming a second set of bit lines on a second metal plane, the second set of bit lines connected to a second set of FinFETs by second contacts having a second height, wherein adjacent bit lines are disposed in different metal planes.

20. The method of claim 18, wherein a fin width is equal to a word line width and is also equal to a perpendicular distance between adjacent word lines, wherein a bit line width is equal to the fin width divided by \sqrt{2}, and wherein the bit lines are disposed on a single plane.
